(19) United States
(12) Patent Application Publication
(10) Pub. No.: US 2013/0240466 A1
(43) Pub. Date: Sep. 19, 2013

(54) PHOTOVOLTAIC PANEL RACKING ASSEMBLY FOR USE IN CONNECTION WITH ROOF INSTALLATION OF PANELS

(71) Applicant: Gregory W. Sponseller, San Antonio, TX (US)

(72) Inventor: Gregory W. Sponseller, San Antonio, TX (US)

(21) Appl. No.: 13/875,135

(22) Filed: May 1, 2013

Related U.S. Application Data
(63) Continuation-in-part of application No. PCT/US2011/059481, filed on Nov. 5, 2011.

(51) Int. Cl. H01L 31/042

(52) U.S. Cl. CPC H01L 31/0422
USPC 211/26

(57) ABSTRACT

A photovoltaic panel racking assembly (60) includes a cylindrically shaped standoff (70) cooperatively adjoined to a specially formed toggle (80) through an all thread rod (100). A nut (101) is sized and shaped to operatively engage with the toggle (80) to fix the relative position of the toggle (80) and the nut (101). A rubber gasket (110) is provided in order to promote watertight sealing upon installation and during use of the racking assembly (60). A relief plate (112) may be provided in order to prevent installation damage to more generally fragile roofing materials such as asphalt shingles or like composite roofing (128). A rubber sleeve (102) is provided in order to facilitate positioning of the toggle (80) during installation of the racking assembly (60). Brackets (180, 200) are described for affixing one or more photovoltaic panels (170) to the racking assembly (60).

### RELATED APPLICATIONS

This application claims all available benefit of and priority to P.C.T. international patent application No. PCT/US2011/059481 filed on Nov. 5, 2011 (designating the United States); U.S. provisional patent application Ser. No. 61/575,436 filed Aug. 22, 2011; U.S. provisional patent application Ser. No. 61/459,701 filed Dec. 17, 2010; and U.S. provisional patent application Ser. No. 61/456,330 filed Nov. 5, 2010. By this reference, the full disclosures, including the drawings, of P.C.T. international patent application No. PCT/US2011/059481; U.S. provisional patent application Ser. No. 61/575,436; U.S. provisional patent application Ser. No. 61/459,701; and U.S. provisional patent application Ser. No. 61/456,330 are incorporated herein as though now set forth in their respective entireties.

### FIELD OF THE INVENTION

The present invention relates to building construction. More specifically, the present invention relates to a novel racking system for roof installation of photovoltaic panels.

### BACKGROUND OF THE INVENTION

After much improvement in the efficiency of photovoltaic panels and decease in cost technological cost, implementation of photovoltaic panel systems remains greatly hampered by installation costs and potential for damage to the roof section upon which a system is to be installed.

As a result, the overriding object of the present invention is to improved over the prior art by setting forth an assembly and method of its use for fast, easy and cost effective roof installation of a photovoltaic panel system including, among other advantages, the ability for a single installer to deploy the assembly without need for locating underlying rafters.

### SUMMARY OF THE INVENTION

In accordance with the foregoing objects, the present invention—a photovoltaic panel racking assembly for use in connection with roof installations of photovoltaic panels—generally comprises a cylindrically shaped standoff cooperatively adjoined to a specially formed toggle through an all thread rod, or similar hardware, and having positioned at an end opposite the standoff a nut that is sized and shaped to operatively engage with the toggle to fix the relative position of one to the other. A rubber or like material gasket is also provided in order to promote watertight sealing upon installation and during use of the racking assembly. Additionally, a relief plate may be provided in order to prevent installation damage to more generally fragile roofing materials such as, for example, asphalt shingles or like composite roofing. Finally, a rubber or like material sleeve is provided in order to facilitate positioning of the toggle during installation of the racking assembly.

Many other features, objects and advantages of the present invention will be apparent to those of ordinary skill in the relevant arts, especially in light of the foregoing discussions and the following drawings, exemplary detailed description and appended claims.

### BRIEF DESCRIPTION OF THE DRAWINGS

Although the scope of the present invention is much broader than any particular embodiment, a detailed description of the preferred embodiment follows together with illustrative figures, wherein like reference numerals refer to like components, and wherein:

FIG. 1 shows, in a perspective view, the preferred embodiment of the photovoltaic panel racking assembly of the present invention;

FIG. 2 shows, in a front elevational view, the photovoltaic panel racking assembly of FIG. 1;

FIG. 3 shows, in a perspective view, details of the preferred embodiment of a standoff as implemented in the photovoltaic panel racking assembly of FIG. 1;

FIG. 4 shows, in a cross sectional view taken through cut line 4-4 of FIG. 3, various additional details of the standoff of FIG. 3;

FIG. 5 shows, in a top perspective view, details of the preferred embodiment of a toggle as implemented in the photovoltaic panel racking assembly of FIG. 1;

FIG. 6 shows, in a bottom perspective view, various additional details of the toggle of FIG. 5;

FIG. 7 shows, in a top plan view, various still further details of the toggle of FIG. 5;

FIG. 8 shows, in a front elevational view, the toggle of FIG. 5 as oriented in a first generally extreme position with respect to an all thread rod implemented in the photovoltaic panel racking assembly of FIG. 1;

FIG. 9 shows, in a left side elevational view, the toggle of FIG. 5 as oriented with respect to the all thread rod in the position of FIG. 8;

FIG. 10 shows, in a front elevational view, the toggle of FIG. 5 as oriented in a second generally extreme position with respect to the all thread rod implemented in the photovoltaic panel racking assembly of FIG. 1;

FIG. 11 shows, in a right side elevational view, the toggle of FIG. 5 as oriented with respect to the all thread rod in the position of FIG. 10;

FIG. 12 shows, in a partially exploded perspective view, the photovoltaic panel racking assembly of FIG. 1 as configured and positioned for installation on a roof section;

FIG. 13 shows, in a perspective view, the photovoltaic panel racking assembly of FIG. 1 as initially installed through a mounting hole in a roof section;

FIG. 14 shows, in a front elevational view, the photovoltaic panel racking assembly of FIG. 1 as initially installed through a mounting hole in a roof section as shown in FIG. 13 and, in particular, shows the toggle in a state of transition during the course of installation of the racking assembly;

FIG. 15 shows, in a front elevational view generally corresponding to the view of FIG. 14, the photovoltaic panel racking assembly of FIG. 1 in a further state of installation on a roof section;

FIG. 16 shows, in a front elevational view generally corresponding to the view of FIG. 14, the photovoltaic panel racking assembly of FIG. 1 in a still further state of installation on a roof section;

FIG. 17 shows, in a front elevational view generally corresponding to the view of FIG. 14, the photovoltaic panel racking assembly of FIG. 1 in a final state of installation on a roof section;

FIG. 18 shows, in a perspective view, the photovoltaic panel racking assembly of FIG. 1 in the final state of installation of FIG. 17;

FIG. 19 shows, in a cross sectional view taken through cut line 19-19 of FIG. 18, various additional details of the photovoltaic panel racking assembly of FIG. 1 in the final state of installation of FIG. 17;

FIG. 20 shows, in a partially exploded perspective view, the preferred embodiment of an extension of the present invention for providing an extended mounting surface for one or more photovoltaic panels;

FIG. 21 shows, in a perspective view, the preferred embodiment of an assembly jig as particularly adapted for use in connection with the extension of FIG. 20;

FIG. 22 shows, in a bottom plan view, the various details of the assembly jig of FIG. 21;

FIG. 23 shows, in a perspective view, various details of the installation of the extension of FIG. 20 and, in particular, shows the manner of use of the assembly jig of FIG. 21;

FIG. 24 shows, in a perspective view, the extension of FIG. 20 in a final state of installation;

FIG. 25 shows, in a partially exploded perspective view, the preferred embodiment of a further extension of the present invention for securing a photovoltaic panel to the mounting surface of FIG. 20 and, in particular, shows a panel mounting bracket as particularly useful for securing an end panel the mounting surface of FIG. 20;

FIG. 26 shows, in a detail view located by reference 26 of FIG. 25, various details of the panel mounting bracket of FIG. 25 and its associated hardware;

FIG. 27 shows, in a perspective view, the panel mounting bracket of FIG. 25 as utilized to secure an end photovoltaic panel atop the mounting surface of FIG. 20;

FIG. 28 shows, in left side elevational view, various details of the utilization of FIG. 27;

FIG. 29 shows, in a detail view located by reference 29 of FIG. 28, various additional details of the of the utilization of FIG. 27;

FIG. 30 shows, in a partially exploded perspective view, the preferred embodiment of a still further extension of the present invention for securing a pair of photovoltaic panels to the mounting surface of FIG. 20 and, in particular, shows an integrated inter-panel mounting bracket and grounding clip as particularly useful for securing a pair of end panels to the mounting surface of FIG. 20;

FIG. 31 shows, in a top perspective view, various details of the integrated inter-panel mounting bracket and grounding clip of FIG. 30;

FIG. 32 shows, in a bottom perspective view, various details of the integrated inter-panel mounting bracket and grounding clip of FIG. 30;

FIG. 33 shows, front elevational view, various details of the integrated inter-panel mounting bracket and grounding clip of FIG. 30;

FIG. 34 shows, in a right side elevational view, various details of the integrated inter-panel mounting bracket and grounding clip of FIG. 30;

FIG. 35 shows, in a left side elevational view, the integrated inter-panel mounting bracket and grounding clip of FIG. 30 as utilized to secure a pair of photovoltaic panels atop the mounting surface of FIG. 20;

FIG. 36 shows, in a perspective view, various details of the utilization of FIG. 35;

FIG. 37 shows, in a top plan view, various additional details of the utilization of FIG. 35;

FIG. 38 shows, in a perspective view, various details for utilization of the photovoltaic panel racking assembly of FIG. 1 in connection with a tile roof and, in particular, shows various details of the initial step for preparation of the tile roof for use of the photovoltaic panel racking assembly;

FIG. 39 shows, in a perspective view generally corresponding to the view of FIG. 38, various details of a further step for preparation of the tile roof for use of the photovoltaic panel racking assembly;

FIG. 40 shows, in a top plan view generally corresponding to the view of FIG. 38, various details of a still further step for preparation of the tile roof for use of the photovoltaic panel racking assembly;

FIG. 41 shows, in a top plan view generally corresponding to the view of FIG. 38, various details of the final step for preparation of the tile roof for use of the photovoltaic panel racking assembly;

FIG. 42 shows, in a front elevational view, the photovoltaic panel racking assembly of FIG. 1 as installed for use in connection with a tile roof;

FIG. 43 shows, in a perspective view, the installation of FIG. 42;

FIG. 44 shows, in a partially exploded perspective view, various details of an alternatively preferred embodiment of the photovoltaic panel racking assembly of the present invention;

FIG. 45 shows, in a detail view located by reference 45 of FIG. 44, various additional details of the photovoltaic panel racking assembly of FIG. 44;

FIG. 46 shows, in a front elevational view, various details of the photovoltaic panel racking assembly of FIG. 44 as installed on a roof section;

FIG. 47 shows, in a perspective view, various additional details the photovoltaic panel racking assembly of FIG. 44 as installed on a roof section;

FIG. 48 shows, in a perspective view, various details of a first preferred embodiment of a standoff as implemented in a second alternatively preferred embodiment of the photovoltaic panel racking assembly of the present invention;

FIG. 49 shows, in a right side elevational view, various additional details of the standoff of FIG. 48;

FIG. 50 shows, in a cross sectional view taken through cut line 50-50 of FIG. 49, various still further details of the standoff of FIG. 48;

FIG. 51 shows, in a perspective view, various details of the installation and use of the second alternatively preferred embodiment of the photovoltaic panel racking assembly of the present invention and, in particular, shows utilization of the standoff of FIG. 48;

FIG. 52 shows, in a front elevational view, various further details of the installation and use of FIG. 51;

FIG. 53 shows, in a perspective view, various details of a second preferred embodiment of a standoff as implemented in the second alternatively preferred embodiment of the photovoltaic panel racking assembly of the present invention;

FIG. 54 shows, in a right side elevational view, various additional details of the standoff of FIG. 53;

FIG. 55 shows, in a perspective view, various details of the installation and use of the second alternatively preferred embodiment of the photovoltaic panel racking assembly of the present invention and, in particular, shows utilization of the standoff of FIG. 53; and

FIG. 56 shows, in a front elevational view, various further details of the installation and use of FIG. 55.

### DETAILED DESCRIPTION OF THE PREFERRED EMBODIMENT

Although those of ordinary skill in the art will readily recognize many alternative embodiments, especially in light of the illustrations provided herein, this detailed description is exemplary of the preferred embodiment of the present invention—a photovoltaic panel racking assembly for use in connection with roof installation of photovoltaic panels, the scope of which is limited only by the claims appended hereto.

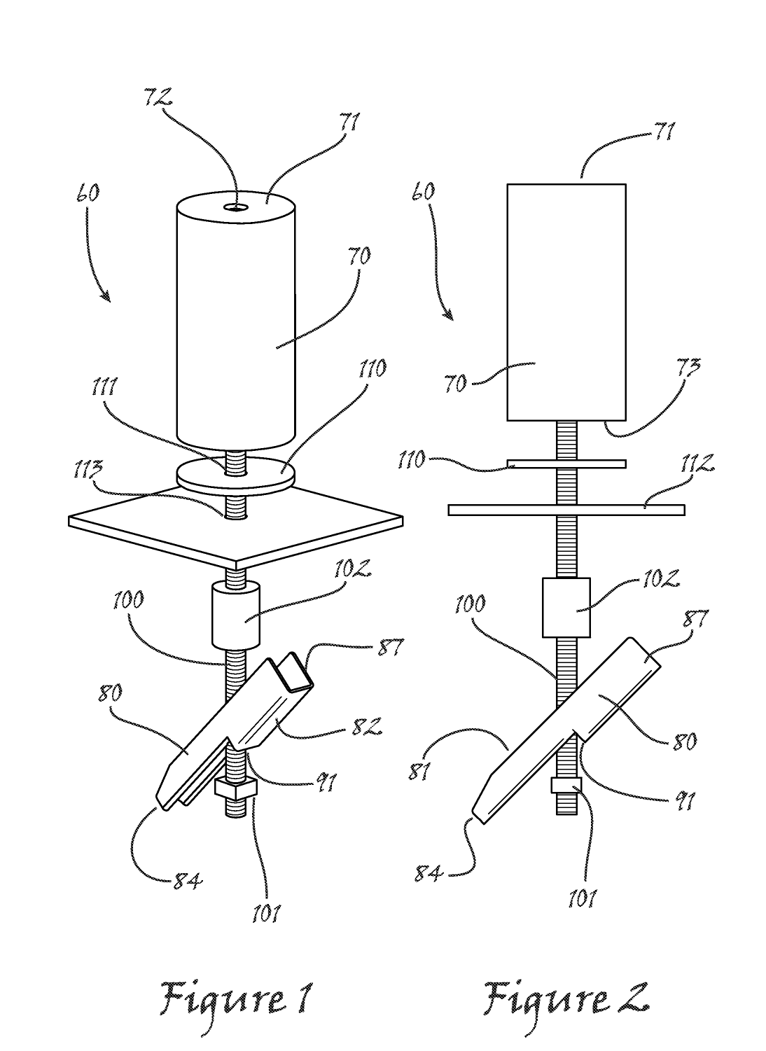

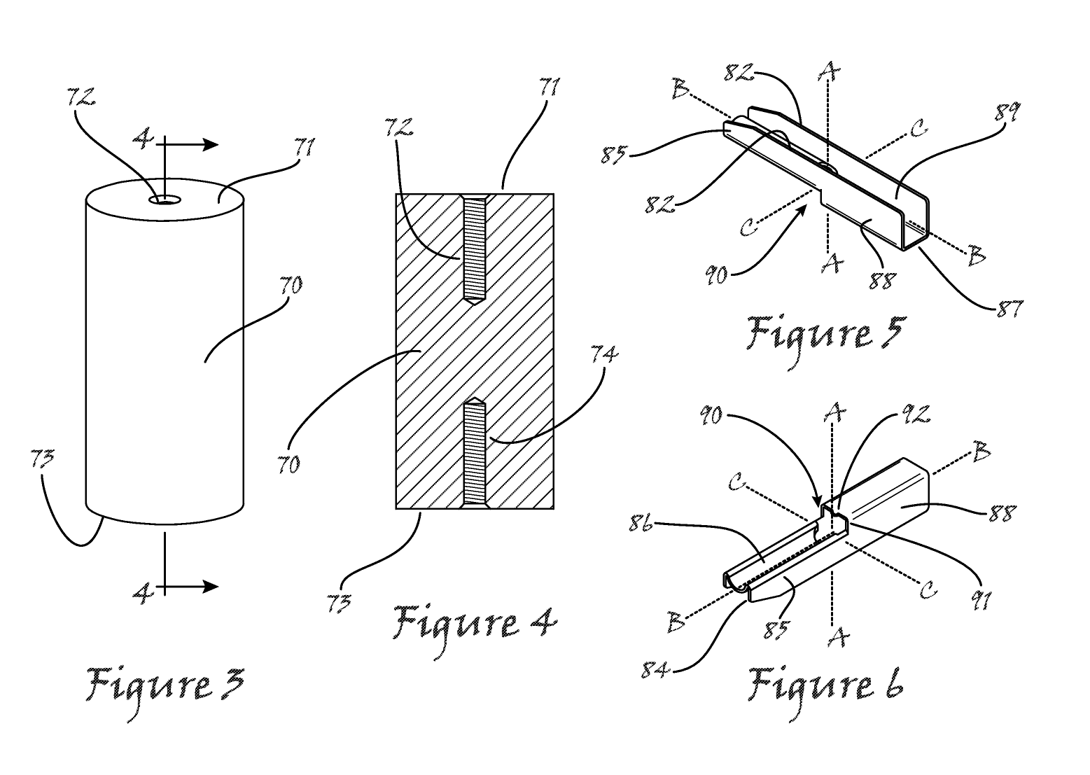

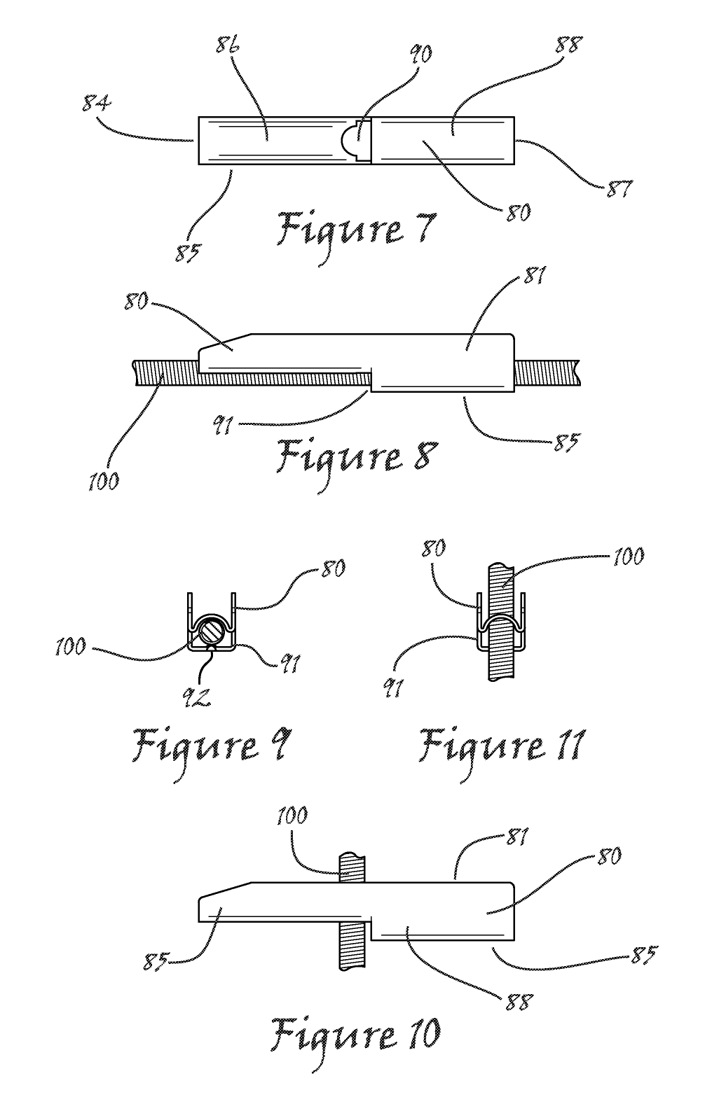

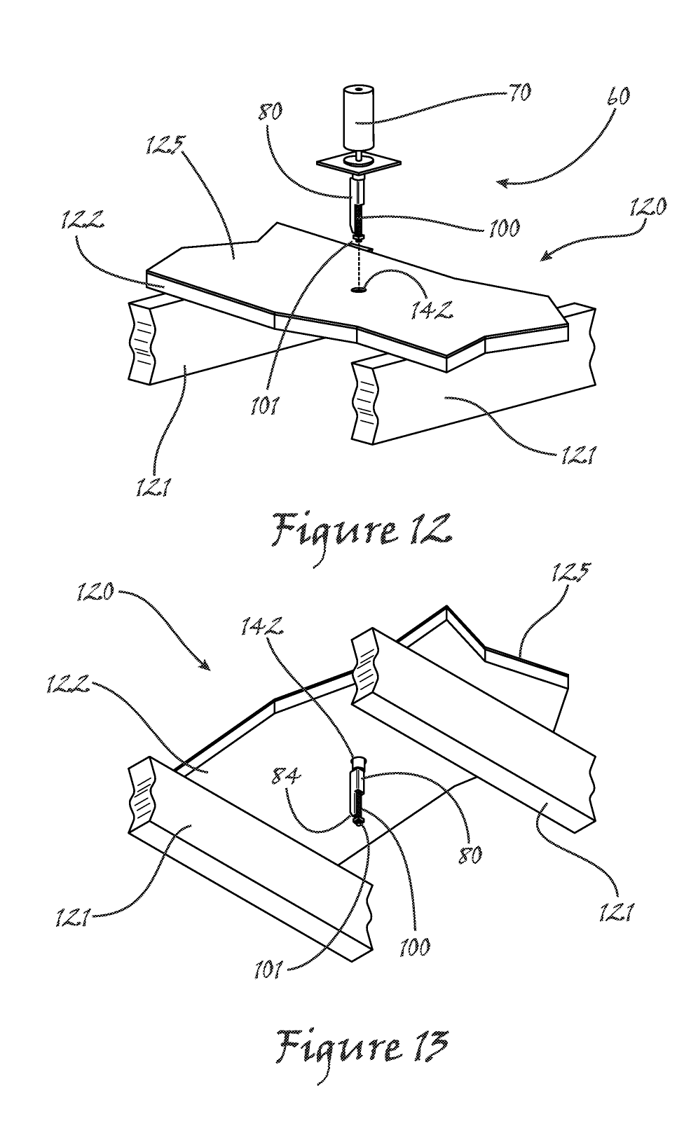

Referring now to the figures and to FIGS. 1 and 2 in particular, a first preferred implementation of the photovoltaic panel racking assembly 60 of the present invention is shown to generally comprise a generally cylindrically shaped standoff 70 cooperatively adjoined to a specially formed toggle 80 through an all thread rod 100 having positioned at an end opposite the standoff 70 a nut 101 that is sized and shaped to operatively engage with the toggle 80 as will be better understood further herein. In a critical aspect of the present invention, as will be better understood further herein with reference to FIGS. 6 and 9, in particular, a tab-like tongue 92 is formed on a shoulder 91 of the toggle 80. In the most preferred embodiment of the first implementation of the present invention, as will be better understood further herein, a rubber or like material gasket 110 is also provided in order to promote watertight sealing upon installation and during use of the present invention. Additionally, and also as will be better understood further herein, a relief plate 112 may be provided in order to prevent installation damage to more generally fragile roofing materials such as, for example, asphalt shingles or like composite roofing 125. In any case, a rubber or like material sleeve 102 is provided and cooperates with the previously noted tongue 91 in order to facilitate positioning of the toggle 80 during installation of the racking assembly 60.

As particularly shown in FIGS. 3 and 4, the standoff 70 is formed of a structural solid such as, for example, aluminum or steel and, in a critical aspect of the present invention, is generally cylindrical in shape. Additionally, as also shown in the figures, the standoff 70 of the first preferred implementation of the photovoltaic panel racking assembly 60 of the present invention comprises at its first, top end 71 a first preferably tapped, longitudinally oriented hole 72, which, as will be better understood further herein, is adapted for receiving various mounting hardware such as, for example, a self-tapping machine screw 151 or the like as may be utilized in the further use of the racking assembly 60. Likewise, the standoff 70 of the first preferred implementation of the photovoltaic panel racking assembly 60 of the present invention also comprises and at its second, bottom end 73 a second preferably tapped, longitudinally oriented hole 74, which, as will also be better understood further herein, is sized, threaded and otherwise adapted to operatively receive therein one end of the all thread rod 100.

As particularly shown in FIGS. 5 through 11, the toggle 80 as implemented in accordance with the photovoltaic panel racking assembly 60 of the present invention is specially sized and shaped to exhibit various operative characteristics. In particular, the top 81 of the toggle 80 preferably comprises a plurality of coplanar edges 82 and, in any case, is formed to enable generally planar engagement with a substantially flat surface such as, for example, the underside of a roof deck 122 such as may comprise sheathing material. Additionally, the toggle 80 is provided with a central aperture 90 oriented and extending through the toggle 80 from the top 81 of the toggle to the bottom 83 of the toggle 80. Further, the central aperture 90 generally divides the toggle into a first side 85 toward a first end 84 of the toggle and a second side 88 toward a second end 87 of the toggle. In a critical aspect of the present invention, the second side 88 of the toggle 80, as otherwise herein described, is formed to have a mass appreciably greater than the mass of the first side of the toggle 80, also as otherwise herein described.

As particularly shown in FIGS. 5 and 6, the toggle 80 is defined to comprise a vertical axis A running generally through the center of the central aperture 90 and oriented substantially normal to the plane defined by the coplanar edges 82 of the top 81 of the toggle 80. Additionally, the toggle 80 is defined to comprise a longitudinal axis B running from the center of the first end 84 of the toggle 80 perpendicularly through the vertical axis A to the center of the second end 87 of the toggle 80. Finally, the toggle 80 is defined to comprise a transverse (or lateral) axis C running orthogonally through the vertical axis A and the longitudinal axis B.

As shown in the figures, the toggle 80 comprises in its first side 85 a generally downwardly oriented, open-ended trough 86 positioned slightly above and about the longitudinal axis B and further comprises in its second side a generally C-shaped, upwardly oriented channel 89 having an open top and ends. As particularly shown in FIGS. 8 and 9, the trough 86 and channel 89 are sized and otherwise configured such that the toggle 80 is adapted to snuggly but freely receive the all thread rod 100 along the longitudinal axis B through the toggle 80. Additionally, the trough 86 and channel 89 are sized and otherwise configured such that the toggle 80 may freely translate along and roll about the all thread rod 100 when the all thread rod 100 is positioned along the longitudinal axis B, but, when the all thread rod 100 is so positioned, is generally prevented from yawing about the vertical axis A. As particularly shown in FIGS. 10 and 11, the central aperture 90, trough 86 and channel 89 are also sized and otherwise configured such that the toggle 80 is adapted to closely but freely receive the all thread rod 100 along the vertical axis A or along any axis perpendicular to the transverse axis and within the 90 degree arc between the vertical axis and the longitudinal axis extending above the second side 88 of the toggle 80 and below the first side 85 of the toggle 80. Additionally, the central aperture 90, trough 86 and channel 89 are also sized and otherwise configured such that the toggle 80 may freely translate along and yaw about the vertical axis A when the all thread rod 100 is positioned along the vertical axis A. Further still, the central aperture 90, trough 86 and channel 89 are sized and otherwise configured such that the toggle 80 is generally constrained to approximately 90 degrees pitch about the transverse axis C. Finally, a small tab-like tongue 92 is formed at the shoulder 91 of the toggle 80 adjacent to the bottom of the toggle 80. As particularly shown in FIGS. 6 and 9, the tongue 92 projects from the shoulder 91, in a direction generally parallel to the vertical axis A through the toggle 80, such that when the all thread rod 100 is positioned along the longitudinal axis B through the toggle 80, the distal end of the tongue 92 will loosely engage the threads of the all thread rod 100. To this end, at least the distal end of the tongue 92 is sized and shaped in the manner of a pronounced burr such that the distal end of the tongue may readily be received in the groove formed by adjacent threads of the all thread rod 100. In any case, with the sleeve 102 pressed into engagement with the second end 87 of the toggle 80 and with the all thread rod 100 positioned along the longitudinal axis B of the toggle 80 such that the tongue 92 engages the threads of the all thread rod 100, the toggle 80 is prevented from translating along in longitudinal axis B along the all thread rod 100. As will be appreciated by those of ordinary skill in the art, the provision of this tongue feature is a critical aspect of the invention inasmuch as the described operable combination serves to fix the toggle 80 into position during “blind” insertion through a mounting hole 142. In any case, as used herein, the phrase “means for constraining motion about an inserted” cylindrical object such as, for example, an all thread rod 100, a bolt 220 or the like is expressly defined to mean and be limited to the complete structure described in this paragraph and equivalents thereof.

Referring now then to FIGS. 12 through 19, in particular, installation on a typical roof section 120 of the first preferred implementation of the photovoltaic panel racking assembly 60 of the present invention is described. As shown in FIG. 12, the installation begins with preassembly of the various required and optional components of the racking assembly 60. In particular, the all thread rod 100 is inserted into the tapped hole 74 at the second, bottom end 73 of the standoff 70. Preferably, in order to facilitate a watertight seal upon installation of the assembly 60 on the roof section 120, a gasket 110 is then placed in the assembly 60 by inserting the free end of the all thread rod 100 through the mounting hole 111 provided through the gasket 110. In the case of the racking assembly 60 being prepared for use in connection with a roof section comprising composite roofing 125 such as, for example, asphalt shingles or the like, a relief plate 112 is most preferably then next placed in the assembly 60 by inserting the free end of the all thread rod 100 through the mounting hole 113 provided through the relief plate 112, thereby distributing the tightening force of the assembly 60 over a greater area of the composite roofing 125. Next, in order to facilitate positioning of the toggle 80 during installation, as will be better understood further herein, the rubber or like material sleeve 102 is then added to the assembly 60 by placing the sleeve 102 over the free end of the all thread rod 100. In any case, the toggle 80 is then added to the assembly 60 by running the free end of the all thread rod 100 from top to bottom through the central aperture 90 of the toggle 80. Finally, the provided nut 101 is threaded onto the all thread rod 100 to complete the preassembly of the various required and optional components of the racking assembly 60.

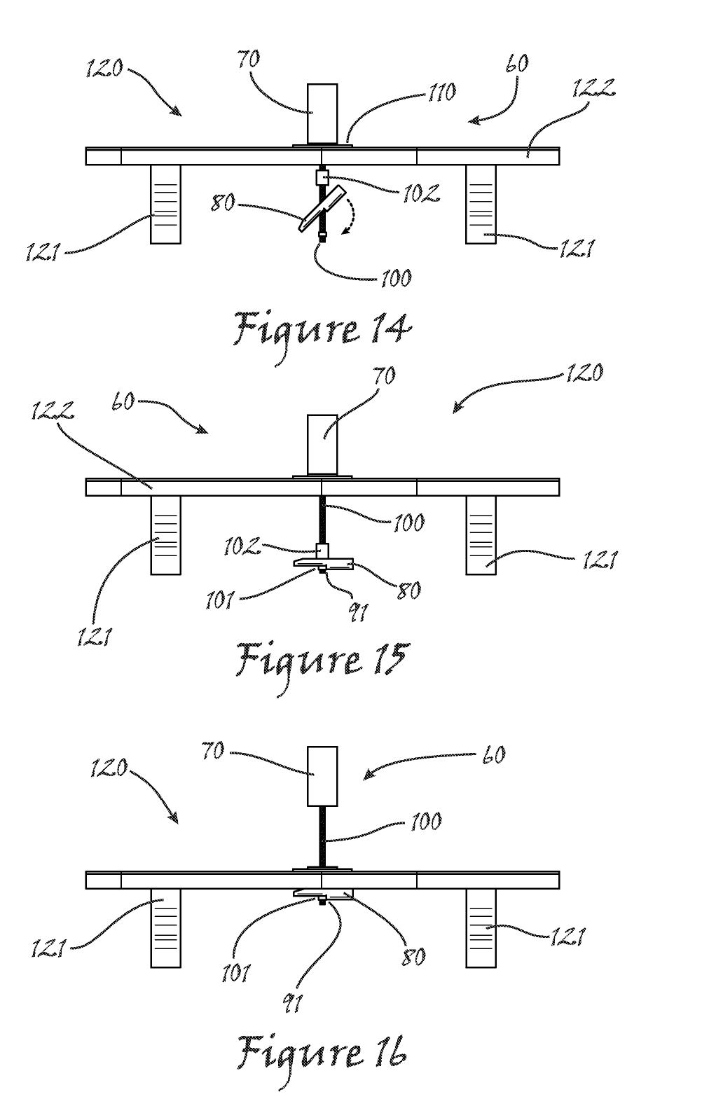

If not already prepared, the roof section 120 is then prepared for installation of the racking assembly 60 by drilling a mounting hole 142 through the composite roofing 125 (and any moisture barrier 123 such as, for example, roofing felt 124 or like tar paper) and the roof deck 122. In a particular advantage of the present invention over the prior art, the mounting hole 142 is placed between rafters 121 rather than being constrained to being centered on a rafter 121. In any case, the preassembled racking assembly 60 is then configured as generally shown in FIG. 12 by orienting the toggle 80 such that its longitudinal axis B lies along the all thread rod 100 with the first end 84 of the toggle 80 resting at least slightly above the nut 101. In order to maintain this positioning and orientation of the toggle 80, the sleeve 102 is pressed down along the all thread rod 100 into firm contact with the second end 87 of the toggle 80, which is prevented from sliding downward due to the engagement, as previously described, of the distal end of the tongue 92 with a groove between adjacent threads of the all thread rod 100. In order to ensure positive positioning of the toggle 80, however, the toggle 80 may be “tightened” against the sleeve 102 by screwing the toggle 80 about the all thread rod 100, in which case the distal end of the tongue acts as a single, partial thread operable with the threading provided about the all thread rod 100. In any case, the end of the assembly 60 generally opposite the standoff 70 is then inserted through the prepared mounting hole 142 into position beneath the roof deck 122 as generally shown in FIG. 13. As the assembly 60 is inserted through the mounting hole 142, the sleeve 102 is manually restrained to free the toggle 80 whereafter the greater mass of the second side 88 of the toggle 80 with respect to the first side 85 of the toggle 80 will cause the toggle 80 to pitch within its previously described constrained motion, as shown in FIG. 14, and fall into the position of FIG. 15. In the alternative, however, the toggle 80 may be freed from its engagement with the sleeve 102 by canting the assembly 60 to press the top 81 of the toggle 80, adjacent its second end 87, against the interior edge of the mounting 142 as the toggle 80 passes therethrough.

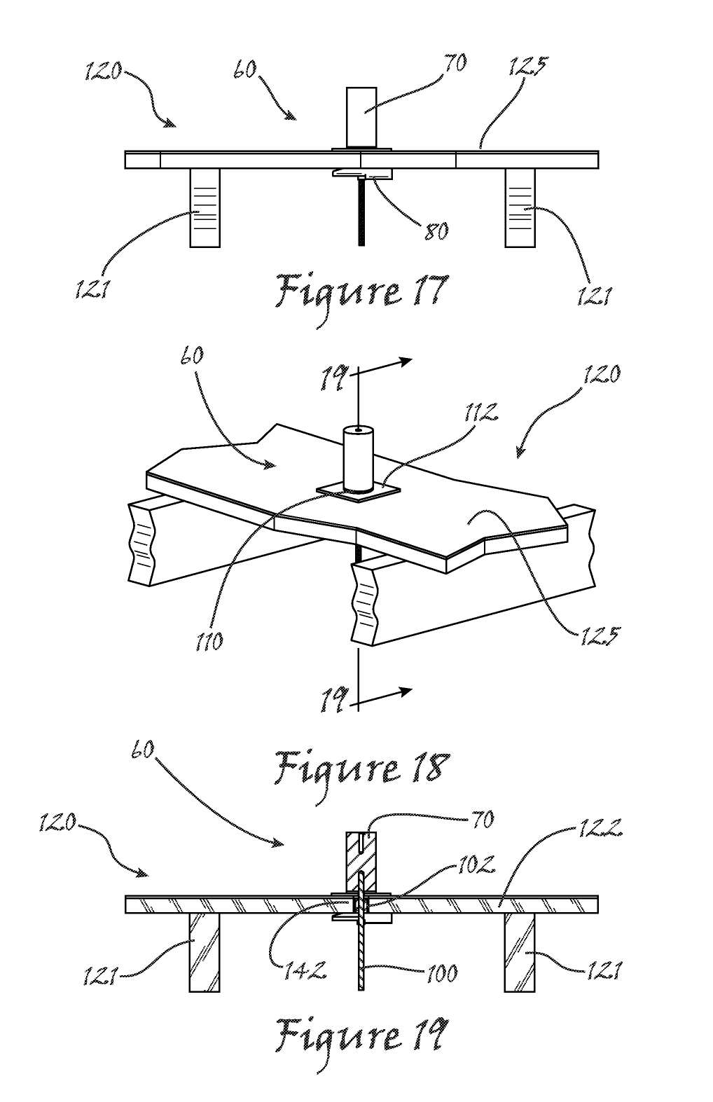

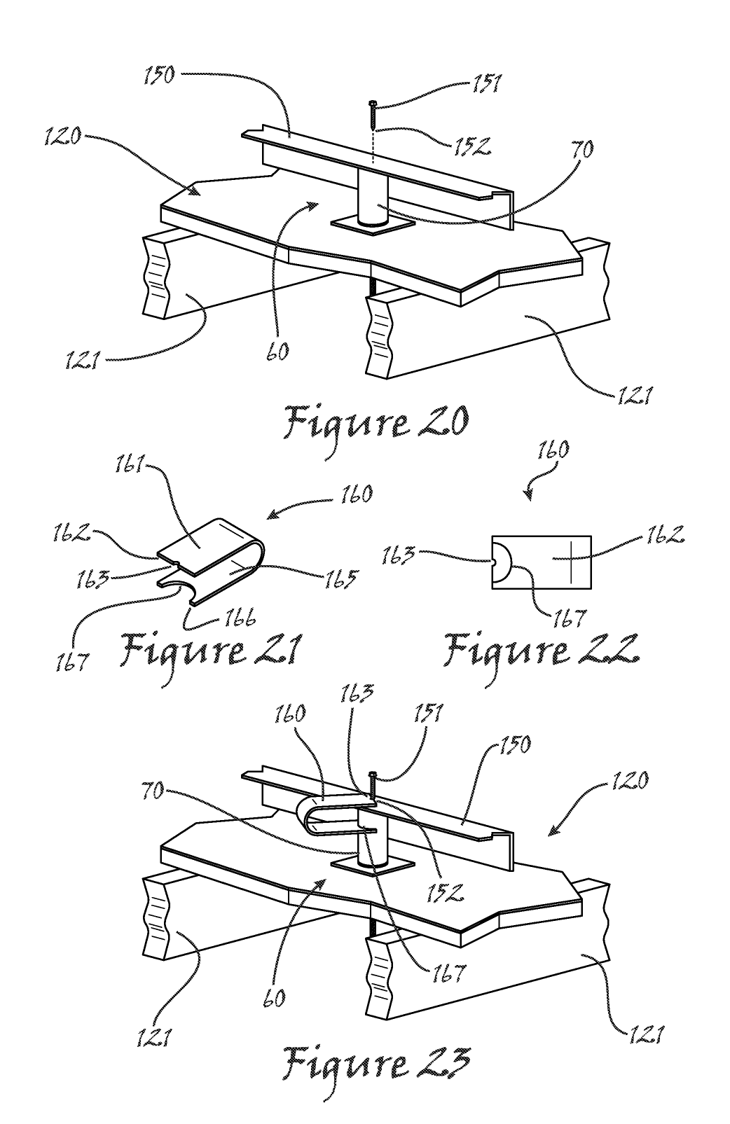

In any case, with the toggle 80 in the position of FIG. 15, jostling or the like will readily bring the toggle 80 into position about the nut 101 such that an edge of the nut 101 abuts against the shoulder 91 formed at the intersection of the central aperture 90 and the channel 89 of the toggle 80. As will be appreciated by those of ordinary skill in the art, especially in light of this exemplary description, the described positioning of the toggle 80 with respect to the nut 101 will cause the rotational position of the nut 101 about the all thread rod 100 to be fixed with the rotational position of the toggle 80 about the all thread rod 100. In order to ensure maintenance of this fixed relationship, the sleeve 102 is slid into position adjacent the top 81 of the toggle 80 as also shown in FIG. 15. In any case, in order to complete installation of the racking assembly 60, the all thread rod 100 is then withdrawn trough the mounting hole 142 until the top 81 of the toggle engages the underside of the roof deck 122 where only slight upward force is required to frictionally fix the position of the toggle 80 about its vertical axis A. With the toggle 80 in fixed position, the standoff 70 and consequently the all thread rod 100 are manually or mechanically rotated to thread the all thread rod 100 through the nut 101, as held in place by the toggle 80, until the assembly is in its fully installed fixed position as shown in FIGS. 17 through 19. As shown in FIG. 19, it is noted that the sleeve 102 will in at this point be contained within the bounds of the mounting hole 142. To this end, in the most preferred embodiment of the present invention, the interior edge of the mounting hole 142 is preferably sized to generally conform to the outer surface of the sleeve 102. In this manner, the sleeve 102 serves a second function as a guide for aligning the centerline through the all thread rod 100, and consequently the centerline of the assembly 60, with the centerline through the mounting hole 142, thereby ensuring fast, accurate and consistent installation of the racking assembly 60 of the present invention.

In an extension of the present invention, as particularly shown in FIGS. 20 through 24, an extended mounting surface for dependently supporting one or more photovoltaic panels 170 may be implemented as an L-shaped, elongate bracket 151 preferably comprising a length of aluminum angle stock. As will be appreciated by those of ordinary skill in the art, the elongate bracket may be placed atop one or more installed photovoltaic panel racking assemblies and secured in place by driving the point 152 of a self-tapping machine screw 151 through the top of the bracket 150 and into the first tapped hole 72 previously described as being provided at the first end 71 of the standoff 70, whereafter the machine screw 151 may be tightened into the tapped hole 72 to secure the bracket 150 in place as generally depicted in FIG. 24. In order to facilitate placement of the self-tapping machine screw 151, however, the present invention further contemplates the option inclusion to the assembly 60 of an assembly jig 160 specially adapted to readily and accurately locate the correct insertion point for the machine screw 151.

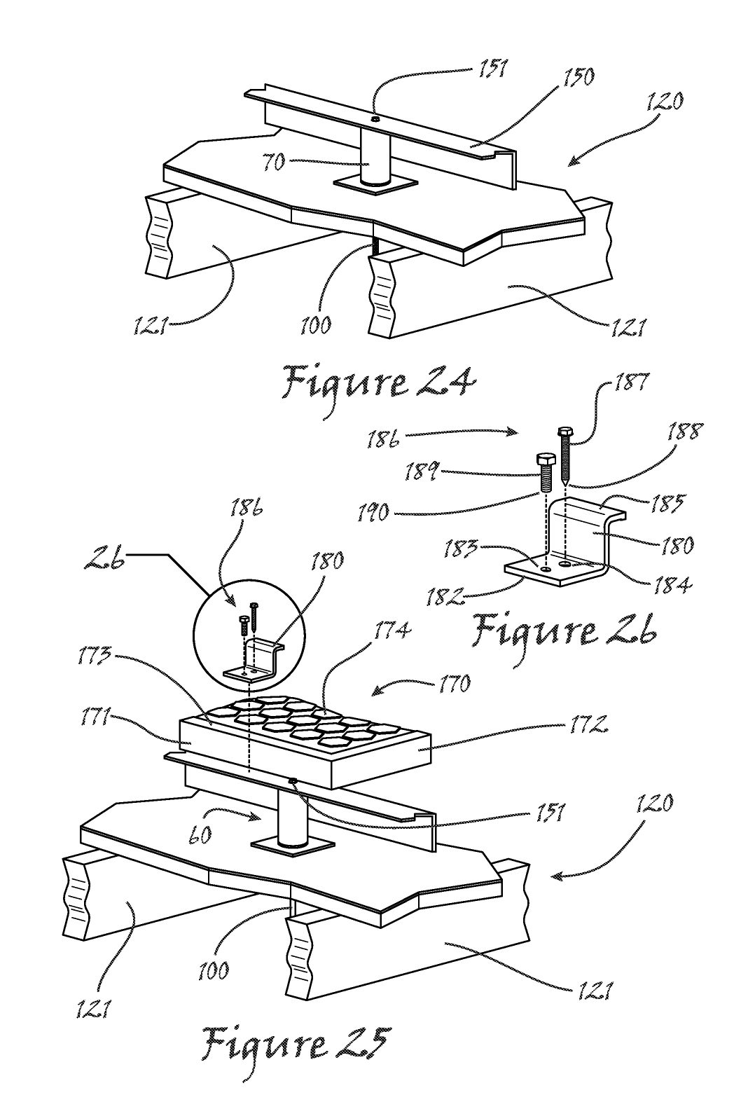

As shown in FIGS. 21 and 22, the assembly jig 160 generally comprises a U-shaped article having a top prong 161 and a bottom prong 165. As shown in the figures, the top prong comprises a preferably semicircular notch 163 at its distal edge 162, the size of this notch 163 being generally of the diameter of the machine screw 151. Similarly, the bottom prong comprises a preferably semicircular notch 167 at its distal edge 166, the size of this notch being generally of the diameter of the standoff 70. As particularly shown in FIG. 23, the origins of the first semicircular notch 163 and of the second semicircular notch 167 are aligned. In this manner, as shown in FIG. 23, simply pressing the distal edge 166 of the bottom prong of the assembly jig 160 against the side of the standoff while the top prong 161 rests atop the bracket 150 locates the correct location for insertion of the self-tapping machine screw 150 according to the location of the notch 163 formed in the distal edge 162 of the top prong 161.

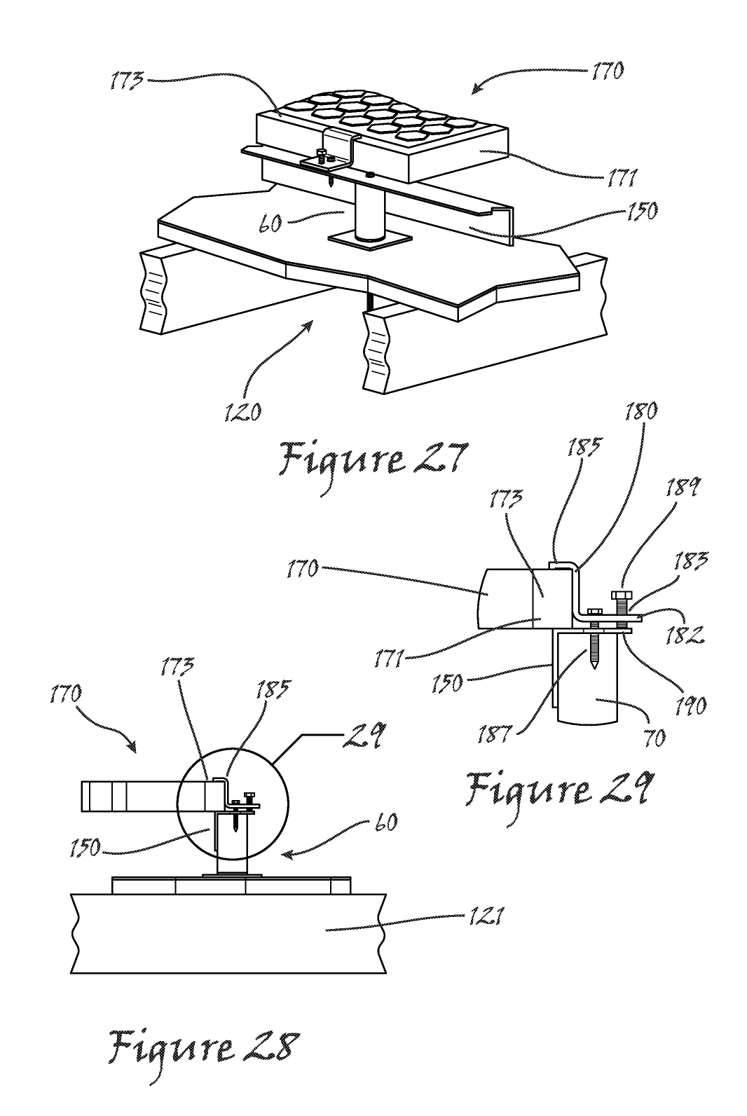

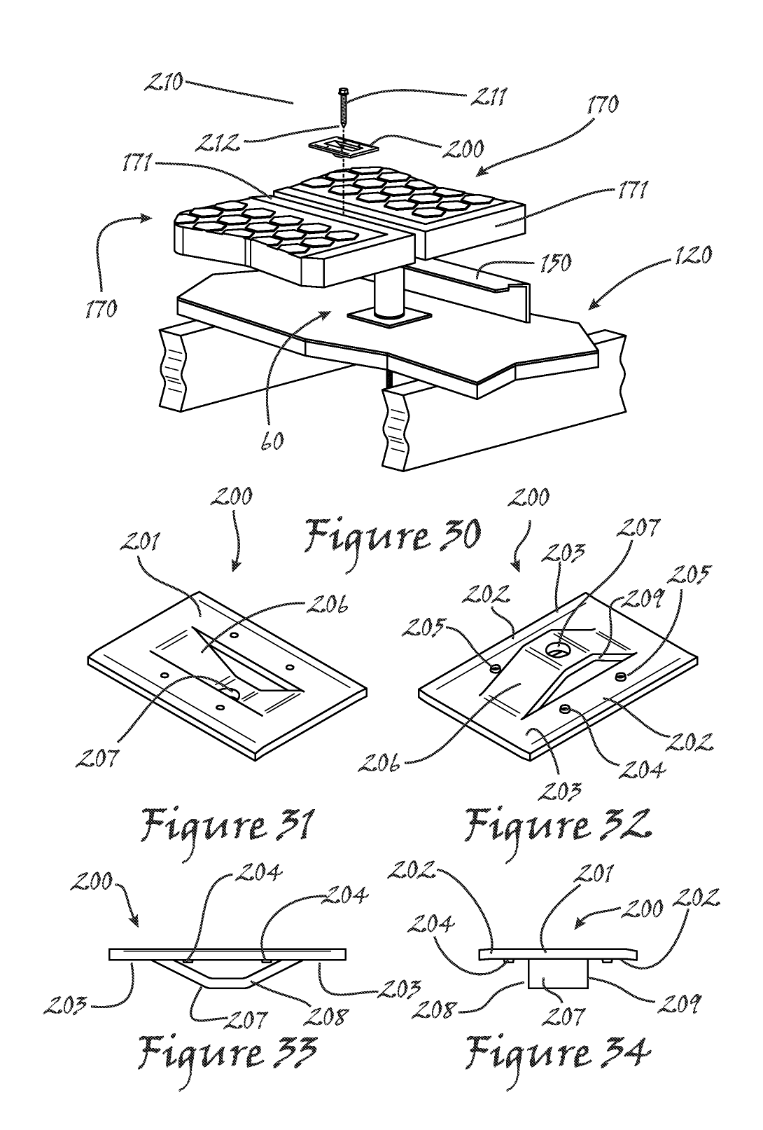

In a further extension of the present invention, novel means for securing a photovoltaic panel 170 atop a provided extended mounting surface 150 are disclosed. In particular, a means for securing a single photovoltaic panel 170 atop a provided extended mounting surface is particularly shown in FIGS. 25 through 29 to generally comprise a panel mounting bracket 180 in the general form of a parallel-S type angle bracket, wherein the panel mounting bracket is provided with means 186 for adjusting the height of the bracket to accommodate a range of thicknesses of photovoltaic panels 170. In particular, as shown in the figures, the base 181 of the panel mounting bracket 180 is provided with a tapped hole 183 generally adjacent its outer edge 182 and an aperture 184 at a more interior location as particularly shown in FIGS. 25 and 26. As shown in FIG. 25, the photovoltaic panel 170 to be mounted is positioned such that a perimetrical edge 172 of the frame 171 about the photovoltaic array 174 is rested atop a portion of the elongate bracket 150 and the panel mounting bracket 180 is positioned such that the clamping arm 185 of the mounting bracket 180 rests on the top 173 of the frame 171 of the photovoltaic panel 170. As shown in FIGS. 28 and 29, a hex head or like bolt 189 having a substantially flat point 190 is inserted through the tapped hole 183 provided in the base 181 of the panel mounting bracket 180 in order to adjust the height of the base 181 above the elongate bracket 150 as necessary to accommodate the height of the frame 171 of the photovoltaic panel 170. The point 188 of a self-tapping machine screw 187 is then inserted through the aperture 184 provided in the base 181 of the panel mounting bracket 180, driven into and through the elongate bracket 150 and tightened in place to secure the clamping arm 185 firmly against the top 173 of the frame 171 of the photovoltaic panel 170, thereby firmly securing the photovoltaic panel 170 in place atop the elongate bracket 150 as particularly shown in FIGS. 27 through 28.

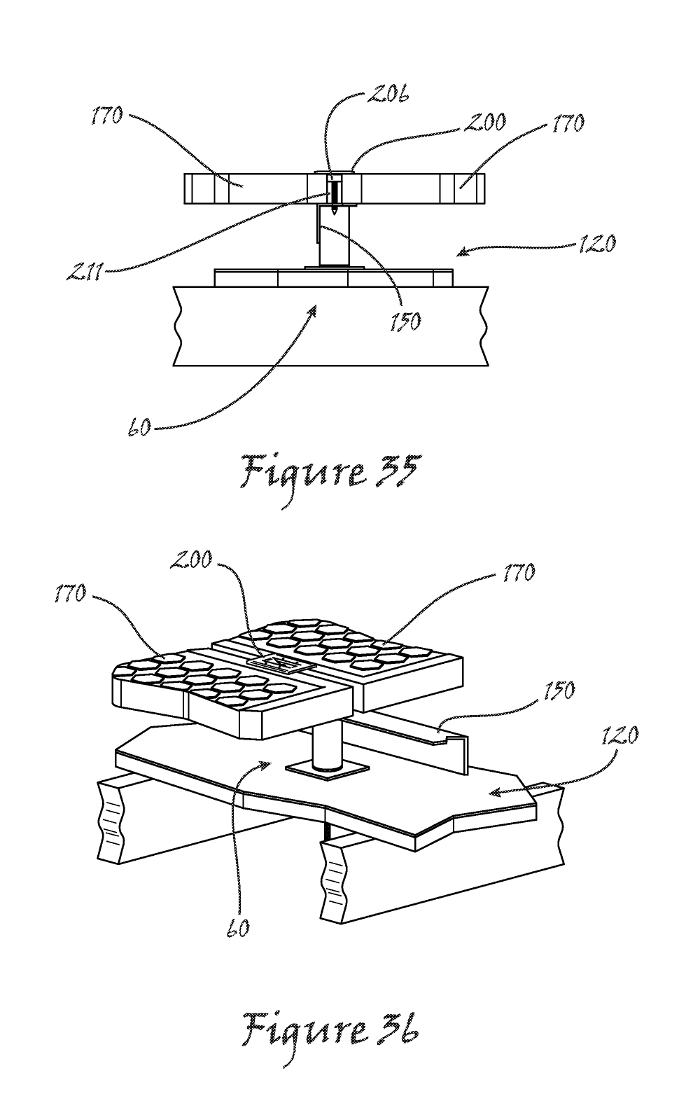

A means for securing a pair of photovoltaic panels 170 atop a provided extended mounting surface 150 is particularly shown in FIGS. 30 through 37 to generally comprise an integrated inter-panel mounting bracket and grounding clip 200, which is preferably stamped or similarly constructed from stainless steel. In addition securing a pair of photovoltaic panels 170 in place atop the elongate bracket 150, the integrated inter-panel mounting bracket and grounding clip 200 of the present invention also provides a grounding bridge between adjacent photovoltaic panels 170. As shown in FIGS. 31 through 34, the integrated inter-panel mounting bracket and grounding clip 200 generally comprises a top surface 201 having formed therein a downwardly projecting mounting tab 206 such that the top surface comprises a plurality of wings 202 extending outward from the first outer edge 208 of the downwardly projecting mounting tab 206 on one side of the integrated inter-panel mounting bracket and grounding clip 200 and extending oppositely outward from the second outer edge 209 of the downwardly projecting mounting tab 206 on the opposite side of the integrated inter-panel mounting bracket and grounding clip 200. The downwardly projecting mounting tab 206 is also provided with a central aperture 207 therethrough for affixation of the integrated inter-panel mounting bracket and grounding clip 200 in place atop the elongate bracket 150, as will be better understood further herein.

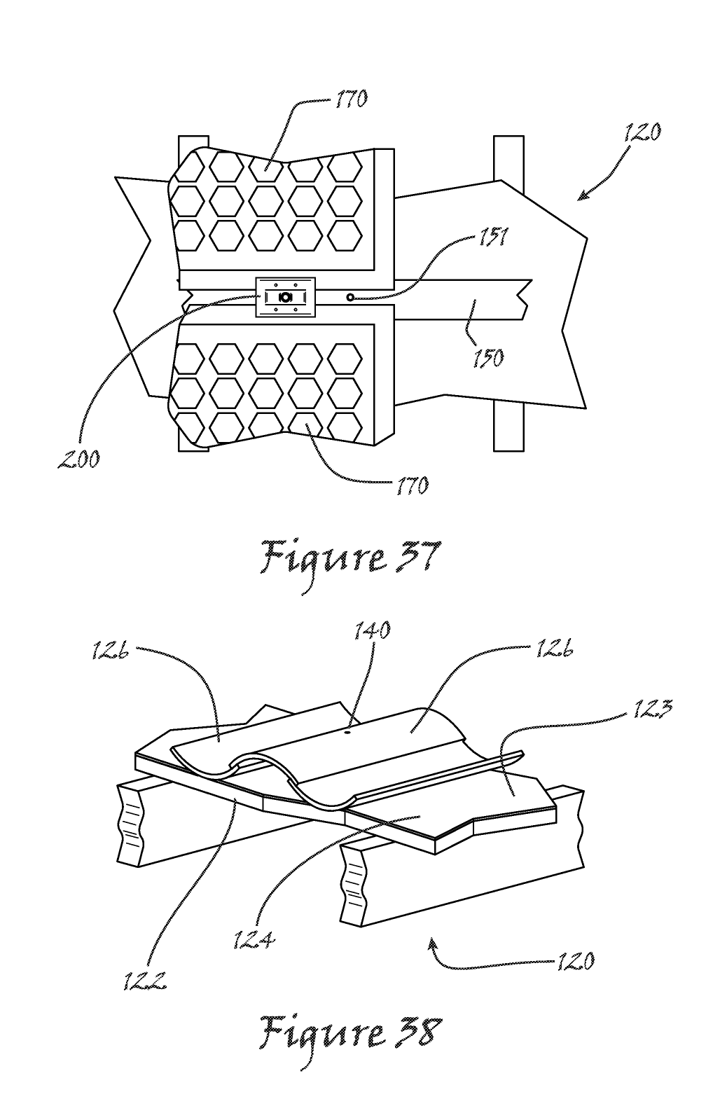

In order that the integrated inter-panel mounting bracket and grounding clip 200 of the present invention may adequately provide a grounding bridge between adjacent photovoltaic panels 170, a plurality of projections 204 are provided on the underside 203 of each wing 203, which projections 204 preferably each comprise a sharp point or edge 205 for embedding into the metal frames 171 of the adjacent photovoltaic panels 170. As will be appreciated by those of ordinary skill in the art, such projections 204 may be readily formed by through punching the wings 202 from the top surface 201 of the integrated inter-panel mounting bracket and grounding clip 200. In any case, the integrated inter-panel mounting bracket and grounding clip 200 of the present invention is utilized by first positioning a pair of photovoltaic panels 170 atop a provided elongate bracket 150, using the opposite outer edges 208, 209 of the downwardly projecting mounting tab 206 of an integrated inter-panel mounting bracket and grounding clip 200 as a guide for spacing of the adjacent photovoltaic panels 170. With the photovoltaic panels 170 properly positioned, as generally shown in FIG. 35, appropriate mounting hardware 210 is used to secure the integrated inter-panel mounting bracket and grounding clip 200 of the present invention in place as well as to force the sharp projections 204 into the metal frames 171 of the adjacent photovoltaic panels 170. In particular, as shown in the figures, a self-tapping machine screw 211 with sharp point 212 is inserted through the central mounting aperture 207 of the downwardly projecting mounting tab 206, driven into and through the elongate bracket 150 and tightened in place to secure the wings 202 firmly against the tops 173 of the frames 171 of the adjacent photovoltaic panels 170, thereby firmly securing the photovoltaic panels 170 in place atop the elongate bracket 150 as particularly shown in FIGS. 35 through 37.

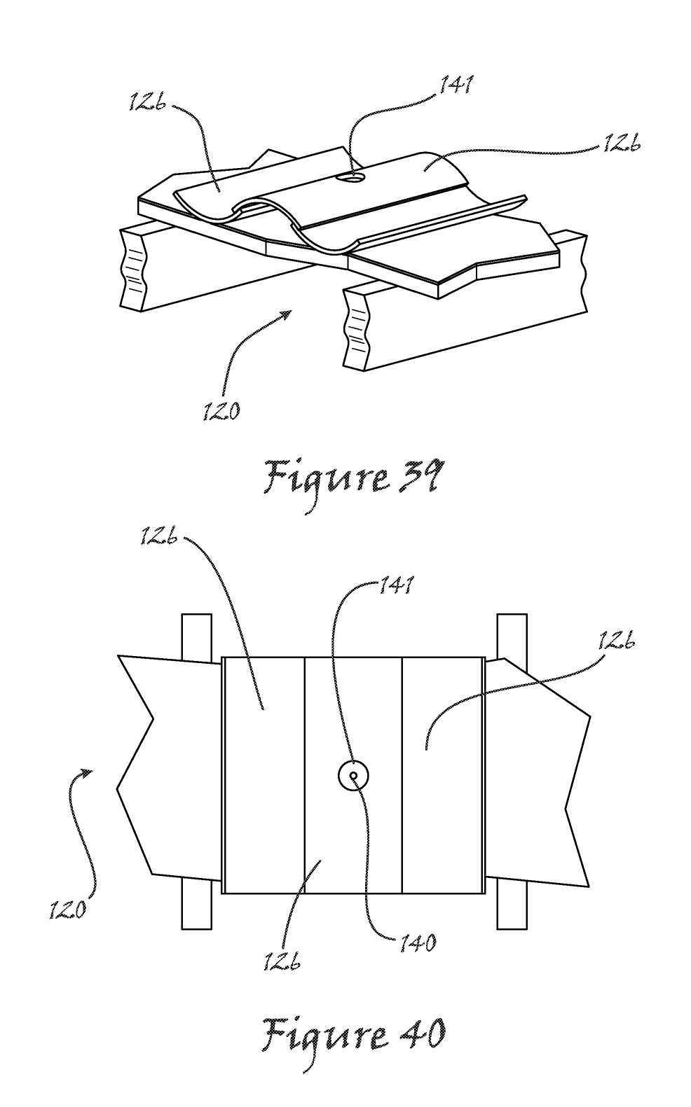

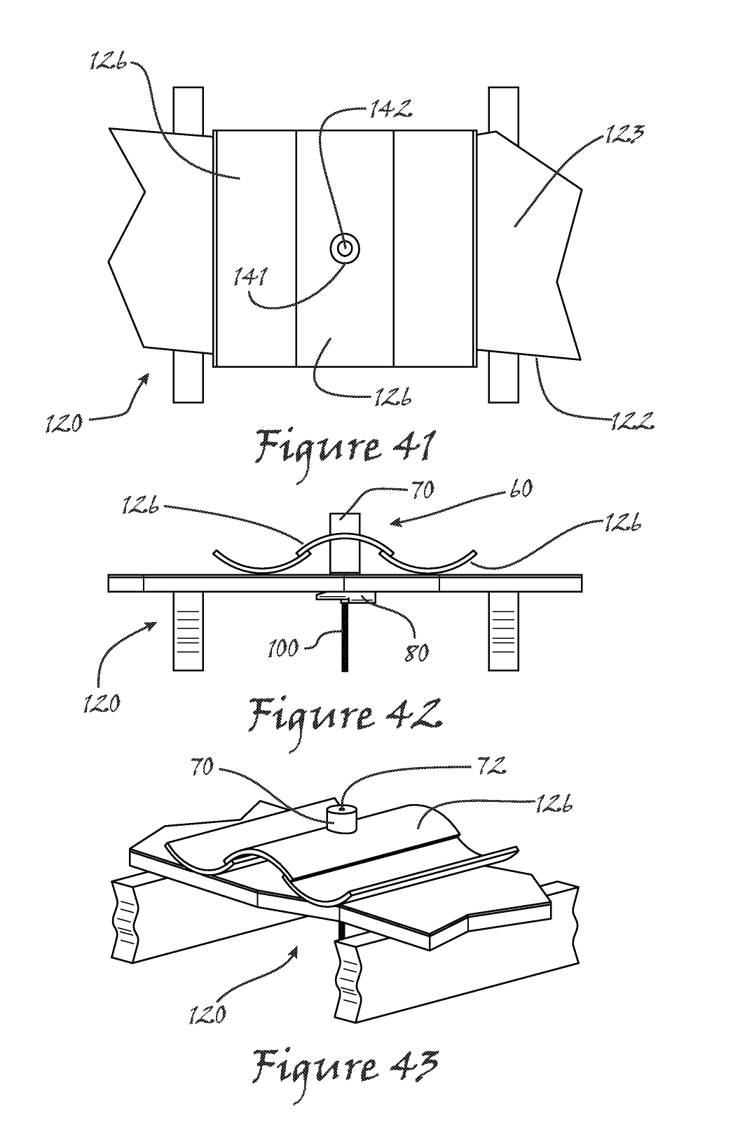

Referring now to FIGS. 38 through 43 in particular, a slight variation in the manner of use of the first preferred implementation of the photovoltaic panel racking assembly 60 of the present invention is described for accommodating utilization in connection with ceramic or similar roofing tiles 126. In particular, it is first noted that because roofing tiles 126 will generally be installed directly atop a moisture barrier 123 over the roofing deck 122, the use of the relief plate 112 is not considered necessary. As a result, the preassembly of the various required and optional components of the racking assembly 60 is a previously described with the exception that the relief 112 is not added to the assembly 60. Turning then to preparation of the roof section 120, and with particular reference to FIG. 38, a small pilot hole 140 is first drilled into and through a selected roofing tile 126 as well as any moisture barrier 123 such as, for example, roofing felt 124 or like tar paper and also through the roof deck 122. With the pilot hole 140 drilled, a clearance hole 141 closing matching the dimension of the standoff 70 is drilled through the selected roofing tile 126 only as particularly shown in FIGS. 39 and 40. With the access gained by the clearance hole 141 through the roofing tile 126 and using the previously established pilot hole 140 as a guide, a larger mounting hole 142 is then drilled through the roofing felt 124 or like tar paper and also through the roof deck 122 as previously discussed and as particularly shown in FIG. 41. With the roof section 120 thus fully prepared, the remaining installation of the first preferred implementation of the photovoltaic panel racking assembly 60 of the present invention proceeds as previously discussed in order to arrive at the arrangement as particularly shown in FIGS. 42 and 43. In the case of this type of installation, however, those of ordinary skill in the art will of course recognize that a roof sealant or the like should be applied about the interface between the clearance hole 141 through the roofing tile 126 and the installed standoff 70.

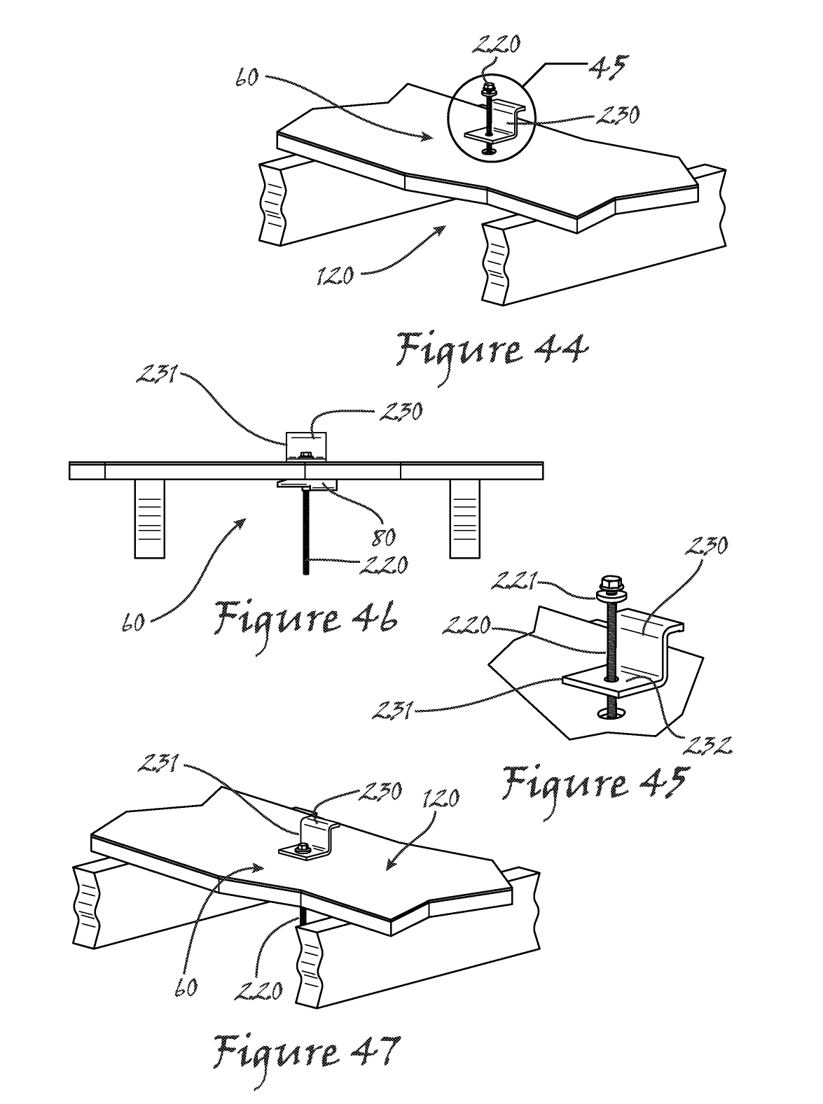

Referring now to FIGS. 44 through 47, a second preferred implementation of the photovoltaic panel racking assembly 60 of the present invention, as particularly useful for mounting extra-assembly hardware 230 or other components such as, for example, a simple mounting bracket 231 is shown to substitute all of the above the roof deck components of the first implementation of the photovoltaic panel racking assembly 60 of the present invention for a washer head bolt 220 and, if required for the particular implementation, a rubber or like material gasket 221 adapted to facilitate a watertight installation. As shown in the figures, the washer head bolt 220 replaces the previously described all thread rod 100, but is otherwise installed as previously discussed.

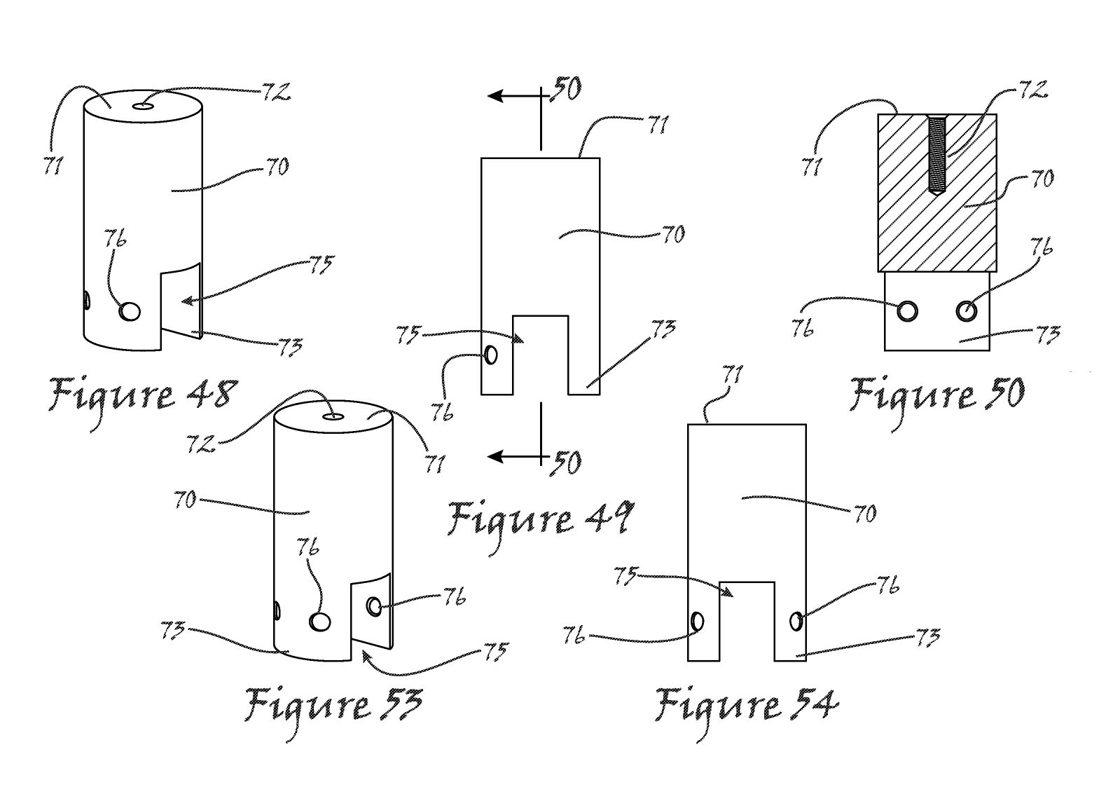

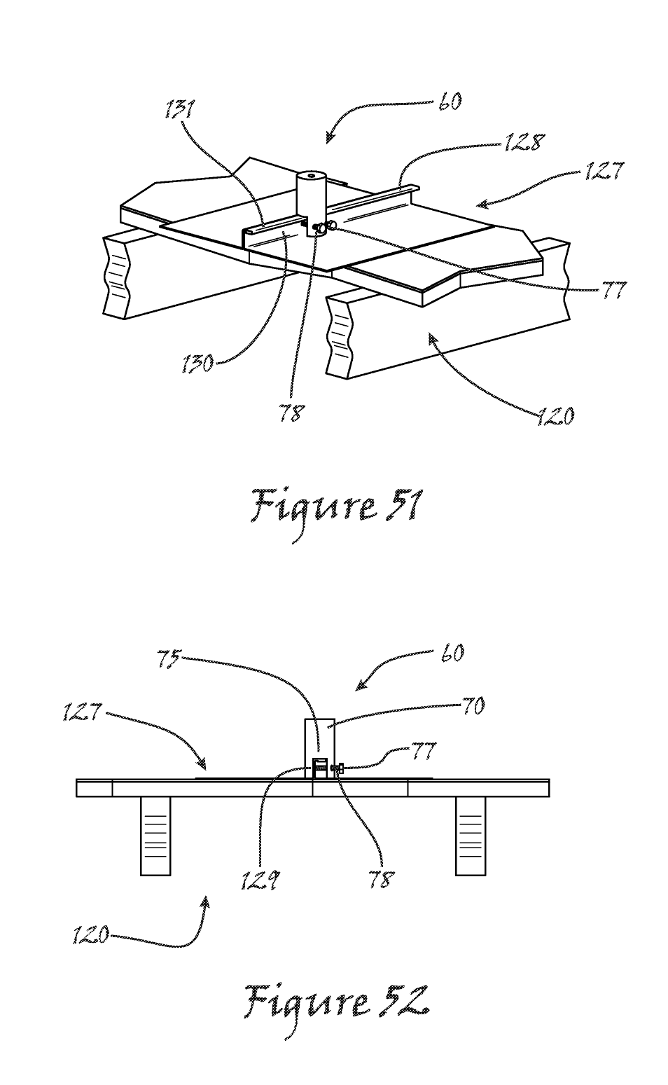

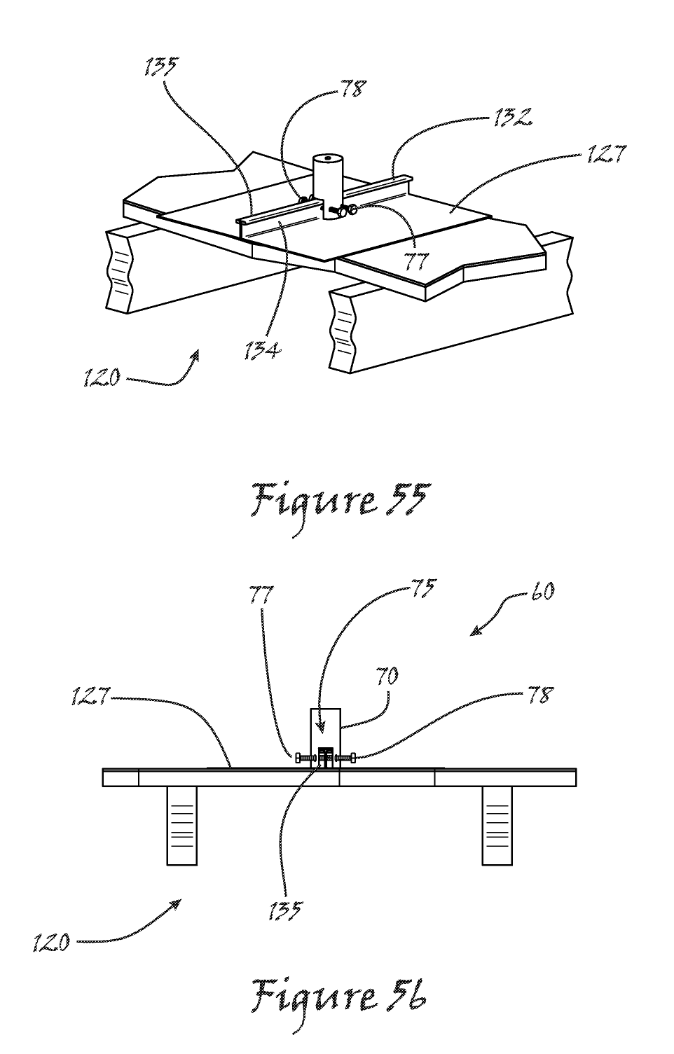

Finally, as particularly shown in FIGS. 48 through 52, an alternative embodiment of the standoff 70 may be implemented for use in connection with standing seam metal roofing 127 such as commonly comprises an L-shaped seam or rib 128 where a first vertical edge 129 rises above the roof surface and is mated with and folded over a second vertical edge 130 rising from the roof surface to form inverted L-shaped profile 131. To accommodate this type of standing seam metal roofing 127, the standoff 70 comprises a slot 75 through its second, bottom end 73 in place of the previously described tapped hole 75. As shown in FIGS. 48 through 50, a plurality of transversely oriented, threaded apertures 76 are provided through one of the tangs formed by the provision of the slot 75. In use, as particularly shown in FIGS. 51 and 52, the modified standoff is placed over and about the L-shaped seam 128 of the standing seam metal roofing 127 with the untapped tang against the unobstructed vertical edge 129 and the tang comprising the threaded apertures 76 positioned facing the opposite vertical edge 130. In position, an appropriate number of hex head or like bolts 78 comprising substantially flat points, or like mounting hardware 77, are utilized to fasten the modified standoff 70 securely in place as shown in FIGS. 51 and 52.

In a slight variation, such as is particularly useful in connection with an installation over a standing seam metal roofing 127 comprising a T-shaped seam or rib 132 wherein a first vertical edge 133 and a second vertical edge 134 are both obstructed by T-arms 135, the modified standoff 70 may be provided with a plurality of transversely oriented, threaded apertures 76 through each of the tangs formed by the provision of the slot 75. In this case, the modified standoff is centered over and about the T-shaped seam 132 of the standing seam metal roofing 127 and fastened from both sides with an appropriate number of hex head or like bolts 78 comprising substantially flat points, or like mounting hardware 77 as shown in FIGS. 55 and 56.

While the foregoing description is exemplary of the preferred embodiment of the present invention, those of ordinary skill in the relevant arts will recognize the many variations, alterations, modifications, substitutions and the like as are readily possible, especially in light of this description, the accompanying drawings and the claims drawn hereto. For example, those of ordinary skill in the art will recognize that if a relief plate 112 is used the installer should during installation apply a roof sealant or the like between the bottom of the relief plate 112 and the roofing material. In any case, because the scope of the present invention is much broader than any particular embodiment, the foregoing detailed description should not be construed as a limitation of the present invention, which is limited only by the claims appended hereto.

What is claimed is:

1. A photovoltaic panel racking assembly for use in connection with roof installation of photovoltaic panels, said photovoltaic panel racking assembly comprising:
a generally cylindrically shaped standoff, said standoff having a longitudinally oriented tapped hole at a first end thereof;
a threaded rod, said threaded rod being inserted at a first end thereof into said tapped hole at said first end of said standoff;
a toggle having inserted through a provided aperture a second end of said threaded rod;
a nut affixed to said second end of said threaded rod and adapted to maintain the insertion of said threaded rod through said aperture of said toggle; and
wherein:
said toggle comprises means for constraining motion about said inserted threaded rod;
said toggle comprises a greater mass on a first side of said aperture than on a second side of said aperture; and
said toggle and said nut are cooperatively adapted to lock into fixed orientation with respect to one another.

2. The photovoltaic panel racking assembly for use in connection with roof installation of photovoltaic panels as recited in claim 1, said photovoltaic panel racking assembly further comprising an extended mounting surface for supporting photovoltaic panels.

3. The photovoltaic panel racking assembly for use in connection with roof installation of photovoltaic panels as recited in claim 2, said photovoltaic panel racking assembly further comprising means for securing an end photovoltaic panel to said extended mounting surface.

4. The photovoltaic panel racking assembly for use in connection with roof installation of photovoltaic panels as recited in claim 2, said photovoltaic panel racking assembly further comprising means for securing an adjacent pair of photovoltaic panels to said extended mounting surface while simultaneously providing a grounding connection between said pair of photovoltaic panels.

5. The photovoltaic panel racking assembly for use in connection with roof installation of photovoltaic panels as recited in claim 4, said photovoltaic panel racking assembly further comprising means for securing an end photovoltaic panel to said extended mounting surface.

6. A photovoltaic panel racking assembly for use in connection with roof installation of photovoltaic panels, said photovoltaic panel racking assembly comprising:
a bolt, said bolt having a threaded end;
a toggle having inserted through a provided aperture said threaded end of said bolt;
a nut affixed to said threaded end of said bolt and adapted to maintain the insertion of said threaded end through said aperture of said toggle; and
wherein:
said toggle comprises means for constraining motion about said inserted threaded end of said bolt;
said toggle comprises a greater mass on a first side of said aperture than on a second side of said aperture; and
said toggle and said nut are cooperatively adapted to lock into fixed orientation with respect to one another.
